(19) United States
(12) Patent Application Publication
(10) Pub. No.: US 2009/0121230 A1
(43) Pub. Date: May 14, 2009

(54) LIGHT EMITTING DEVICE

(75) Inventors: Yunsik JEONG, Gumi-city (KR); Hongki Park, Gumi-city (KR); Sammin Ko, Gumi-city (KR)

Correspondence Address: KED & ASSOCIATES, LLP, P.O. Box 221200, Chantilly, VA, 20153-1200, US

(73) Assignee: LG Electronics Inc.

(21) Appl. No.: 12/353,865

(22) Filed: Jan. 14, 2009

Related U.S. Application Data
(62) Division of application No. 11/965,126, filed on Dec. 27, 2007.

(30) Foreign Application Priority Data
Sep. 21, 2007 (KR) 10-2007-0097021

(51) Int. Cl. H01L 33/00

(52) U.S. Cl. 257/59; 257/E33.004; 257/98; 257/E33.068; 257/E33.062

(57) ABSTRACT

A light emitting device is disclosed. The light emitting device includes a substrate including a thin film transistor, an insulating film disposed over the thin film transistor, a first electrode disposed over the thin film transistor and connected to the thin film transistor, a function layer including at least one of a hole injection layer, a hole transport layer, a light-emitting layer, an electron transport layer, and an electron injection layer, which are sequentially disposed over the first electrode, and a second electrode disposed on the function layer. A thickness of the first electrode is substantially 0.29 to 0.35 times a thickness of the function layer. A thickness of the second electrode is substantially 0.29 to 0.69 times the thickness of the function layer.

This application claims the benefit of Korean Patent Application No. 10-2007-0097021 filed on Sep. 21, 2007, which is hereby incorporated by reference.

### BACKGROUND OF THE DISCLOSURE

1. Field Of The Disclosure

An exemplary embodiment relates to a display device, and more particularly, to a light emitting device.

2. Description of the Background Art

In recent years, as display devices become large-sized, there is an increasing need for flat panel display devices occupying less space. As one of the flat panel display devices, a light emitting device has been in the spotlight.

The light emitting device has excellent characteristics, such as a wide viewing angle, a high response speed, and a high contrast, and can be thus used as pixels of graphic displays, television image displays or a surface light source. Further, the light emitting device is thin and light in weight, having a good color sense, and is thus suitable for the next-generation flat displays.

In particular, the light emitting device is a device that emits light when exciton, which is created through a combination of electrons and holes, drops from an excited state to a ground state in a state where the electrons and holes from an electron injection electrode and a hole injection electrode, respectively, are injected into a light-emitting unit.

In other words, the light emitting device has a single layer or a plurality of organic layers (or inorganic layers) stacked between an anode electrode (the hole injection electrode) and a cathode electrode (the electron injection electrode). The organic layer or the inorganic layer emits light in response to a voltage applied to the electrodes.

Recently, in the light emitting device, active research has been done on adequate numerical values of the electrodes and the organic layers (or the inorganic layers) in order to save power consumption while increasing emission efficiency and improve process efficiency.

### SUMMARY OF THE DISCLOSURE

An exemplary embodiment provides a light emitting device capable of increasing emission efficiency, reducing power consumption, and increasing process efficiency.

In an aspect, a light emitting device comprises a substrate comprising a thin film transistor, an insulating film disposed over the thin film transistor, a first electrode disposed over the thin film transistor and connected to the thin film transistor, a function layer comprising at least one of a hole injection layer, a hole transport layer, a light-emitting layer, an electron transport layer, and an electron injection layer, which are sequentially disposed over the first electrode, and a second electrode disposed on the function layer. A thickness of the first electrode is substantially 0.29 to 0.35 times a thickness of the function layer, and a thickness of the second electrode is substantially 0.29 to 0.69 times the thickness of the function layer.

In another aspect, a light emitting device comprises a substrate comprising a thin film transistor, an insulating film disposed over the thin film transistor, a first electrode disposed over the thin film transistor and connected to the thin film transistor, a function layer comprising at least one of a hole injection layer, a hole transport layer, a light-emitting layer, an electron transport layer, and an electron injection layer, which are sequentially disposed over the first electrode, and a second electrode disposed on the function layer. A thickness of the first electrode is substantially 0.6 to 0.79 times a thickness of the function layer, and a thickness of the second electrode is substantially 0.03 to 0.035 times the thickness of the function layer.

In another aspect, a light emitting device comprises a substrate comprising a thin film transistor, an insulating film disposed over the thin film transistor, a first electrode disposed over the thin film transistor and connected to the thin film transistor, a function layer comprising at least one of a hole injection layer, a hole transport layer, a light-emitting layer, an electron transport layer, and an electron injection layer, which are sequentially disposed over the first electrode, and a second electrode disposed on the function layer. A thickness of the first electrode is substantially 0.29 to 0.35 times a thickness of the function layer, and a thickness of the second electrode is substantially 0.29 to 0.69 times the thickness of the function layer. A highest level of a valence band of a hole injection layer including an inorganic material layer is lower than a highest level of a valence band of the hole injection layer including a organic material without the inorganic material, and a lowest level of a conduction band of a electron injection layer including an inorganic material is lower than a lowest level of a conduction band of the electron injection layer including an organic material without the inorganic material.

In another aspect, a light emitting device comprises a substrate comprising a thin film transistor, an insulating film disposed over the thin film transistor, a first electrode disposed over the thin film transistor and connected to the thin film transistor, a function layer comprising at least one of a hole injection layer, a hole transport layer, a light-emitting layer, an electron transport layer, and an electron injection layer, which are sequentially disposed over the first electrode, and a second electrode disposed on the function layer. A thickness of the first electrode is substantially 0.6 to 0.79 times a thickness of the function layer, and a thickness of the second electrode is substantially 0.03 to 0.035 times the thickness of the function layer. A highest level of a valence band of a hole injection layer including an inorganic material layer is lower than a highest level of a valence band of the hole injection layer including a organic material without the inorganic material, and a lowest level of a conduction band of a electron injection layer including an inorganic material is lower than a lowest level of a conduction band of the electron injection layer including an organic material without the inorganic material.

In another aspect, a light emitting device comprises a substrate comprising a thin film transistor, an insulating film disposed over the thin film transistor, a first electrode disposed over the thin film transistor and connected to the thin film transistor, a function layer comprising at least one of a hole injection layer, a hole transport layer, a light-emitting layer, an electron transport layer, and an electron injection layer, which are sequentially disposed over the first electrode, and a second electrode disposed on the function layer. A thickness of the first electrode is substantially 0.29 to 0.35 times a thickness of the function layer, and a thickness of the second electrode is substantially 0.29 to 0.69 times the thickness of the function layer. The electron injection layer is formed one of lithium fluoride (LiF) or a lithium complex (Liq), and the lithium fluoride performs ionic bond having a stronger polarizability than a polarizability of the lithium complex (Liq)

### BRIEF DESCRIPTION OF THE DRAWINGS

The accompanying drawings, which are included to provide a further understanding of the invention and are incorporated on and constitute a part of this specification, illustrate embodiments of the invention and together with the description serve to explain the principles of the invention. In the drawings:

FIG. 1 is a bock diagram of a light emitting device according to an exemplary embodiment;

FIGS. 2 and 3 are circuit diagrams of a subpixel of the light emitting device;

FIGS. 4 and 5 are cross-sectional views of the light emitting device;

FIGS. 6 to 8 are cross-sectional views of another structure of the light emitting device; and

FIGS. 9 to 11 illustrate various implementations of a color image display method in the light emitting device.

### DETAILED DESCRIPTION OF EMBODIMENTS

Reference will now be made in detail embodiments of the invention examples of which are illustrated in the accompanying drawings.

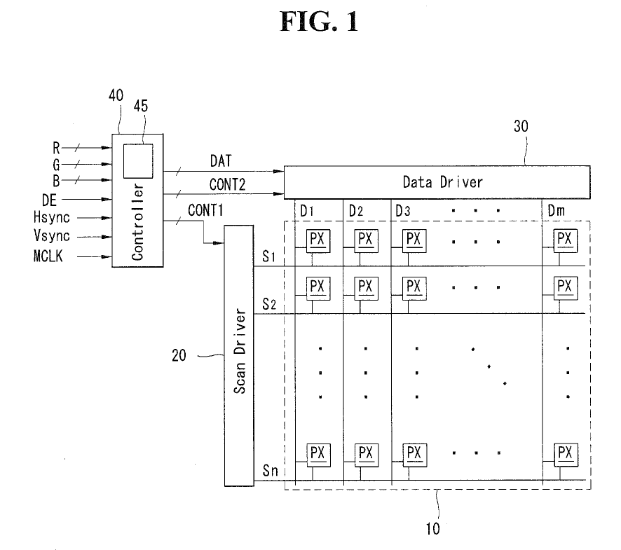

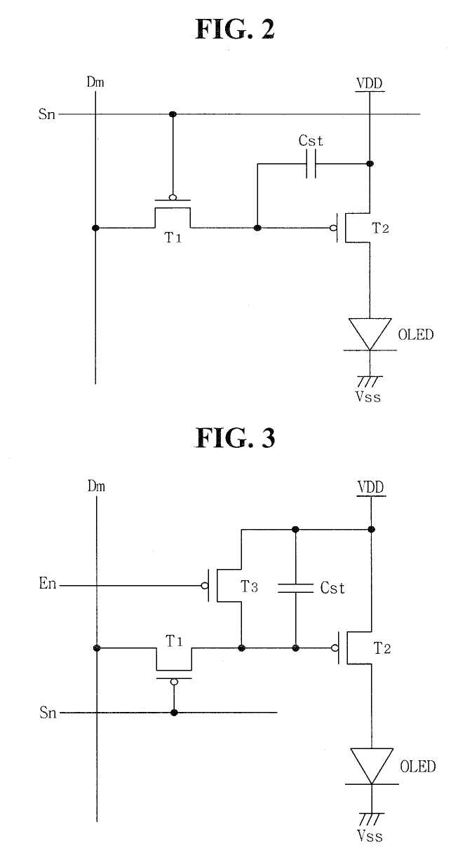

FIG. 1 is a block diagram of a light emitting device according to an exemplary embodiment. FIGS. 2 and 3 are circuit diagrams of a subpixel of the light emitting device.

As shown in FIG. 1, the light emitting device according to the exemplary embodiment includes a display panel 10, a scan driver 20, a data driver 30 and a controller 40.

The display panel 10 includes a plurality of signal lines S1 to Sn and D1 to Dm, a plurality of power supply lines (not shown), and a plurality of subpixels PX connected to the signal lines S1 to Sn and D1 to Dm and the power supply lines in a matrix form.

The plurality of signal lines S1 to Sn and D1 to Dm may include the plurality of scan lines S1 to Sn for sending scan signals and the plurality of data lines D1 to Dm for sending data signals. Each power supply line may send voltages such as a power voltage VDD to each subpixel PX.

Although the signal lines include the scan lines S1 to Sn and the data lines D1 to Dm in FIG. 1, the exemplary embodiment is not limited thereto. The signal lines may further include erase lines (not shown) for sending erase signals depending on a driving manner.

However, an erase line may not be used to send an erase signal. The erase signal may be sent through another signal line. For instance, although it is not shown, the erase signal may be supplied to the display panel 10 through the power supply line in case that the power supply line for supplying the power voltage VDD is formed.

As shown in FIG. 2, the subpixel PX may include a switching thin film transistor T1 for sending the data signal in response to the scan signal sent through the scan line Sn, a capacitor Cst for storing the data signal, a driving thin film transistor T2 producing a driving current corresponding to a voltage difference between the data signal stored in the capacitor Cst and the power voltage VDD, and a light emitting diode (OLED) emitting light corresponding to the driving current.

As shown in FIG. 3, the subpixel PX may include a switching thin film transistor T1 for sending the data signal in response to the scan signal sent through the scan line Sn, a capacitor Cst for storing the data signal, a driving thin film transistor T2 producing a driving current corresponding to a voltage difference between the data signal stored in the capacitor Cst and the power voltage VDD, a light emitting diode (OLED) emitting light corresponding to the driving current, and an erase switching thin film transistor T3 for erasing the data signal stored in the capacitor Cst in response to an erase signal sent through an erase line En.

When the light emitting device is driven in a digital driving manner that represents a gray scale by dividing one frame into a plurality of subfields, the pixel circuit of FIG. 3 can control an emission time by supplying an erase signal to a subfield whose a light-emission is shorter than an addressing time. The pixel circuit of FIG. 3 has an advantage capable of reducing a lowest luminance of the light emitting device.

A difference between driving voltages, e.g. the power voltages VDD and Vss of the light emitting device may change depending on the size of the display panel 10 and a driving manner. A magnitude of the driving voltage is shown in the following Tables 1 and 2. Table 1 indicates a driving voltage magnitude in case of a digital driving manner, and Table 2 indicates a driving voltage magnitude in case of an analog driving manner.

TABLE 1

| Size (S) of display | | | |
|---|---|---|---|
| panel | VDD-Vss (R) | VDD-Vss (G) | VDD-Vss (B) |
| S < 3 inches | 3.5-10 (V) | 3.5-10 (V) | 3.5-12 (V) |
| 3 inches < S < 20 | 5-15 (V) | 5-15 (V) | 5-20 (V) |
| inches | | | |
| 20 inches < S | 5-20 (V) | 5-20 (V) | 5-25 (V) |

TABLE 2

| Size (S) of display panel | VDD-Vss (R, G, B) |
|---|---|
| S < 3 inches | 4~20 (V) |
| 3 inches < S < 20 inches | 5~25 (V) |
| 20 inches < S | 5~30 (V) |

Referring again to FIG. 1, the scan driver 20 is connected to the scan lines S1 to Sn of the display panel 10 to apply scan signals capable of turning on the switching thin film transistor T1 to the scan lines S1 to Sn, respectively.

The data driver 30 is connected to the data lines D1 to Dm of the display panel 10 to apply data signals indicating an output video signal DAT to the data lines D1 to Dm, respectively. The data driver 30 may include at least one data driving integrated circuit (IC) connected to the data lines D1 to Dm.

The data driving IC may include a shift register, a latch, a digital-to-analog (DA) converter, and an output buffer connected to one another in the order named.

When a horizontal sync start signal (STH) (or a shift clock signal) is received, the shift register can send the output video signal DAT to the latch in response to a data clock signal (HLCK). In case that the data driver 30 includes a plurality of data driving ICs, a shift register of a data driving IC can send a shift clock signal to a shift register of a next data driving IC.

The latch memorizes the output video signal DAT, selects a gray voltage corresponding to the memorized output video signal DAT in response to a load signal, and sends the gray voltage to the output buffer.

The DA converter selects the corresponding gray voltage in response to the output video signal DAT and sends the gray voltage to the output buffer.

The output buffer outputs an output voltage (serving as a data signal) received from the DA converter to the data lines D1 to Dm, and maintains the output of the output voltage for 1 horizontal period (1H).

The controller 40 controls an operation of the scan driver 20 and an operation of the data driver 30. The controller 40 may include a signal conversion unit 45 that gamma-converts input video signals R, G and B into the output video signal DAT and produces the output video signal DAT.

The controller 40 produces a scan control signal CONT1 and a data control signal CONT2, and the like. Then, the controller 40 outputs the scan control signal CONT1 to the scan driver 20 and outputs the data control signal CONT2 and the processed output video signal DAT to the data driver 30.

The controller 40 receives the input video signals R, G and B and an input control signal for controlling the display of the input video signals R, G and B from a graphic controller (not shown) outside the light emitting device. Examples of the input control signal include a vertical sync signal Vsync, a horizontal sync signal Hsync, a main clock signal MCLK and a data enable signal DE.

Each of the driving devices 20, 30 and 40 may be directly mounted on the display panel 10 in the form of at least one IC chip, or may be attached to the display panel 10 in the form of a tape carrier package (TCP) in a state where the driving devices 20, 30 and 40 each are mounted on a flexible printed circuit film (not shown), or may be mounted on a separate printed circuit board (not shown).

Alternatively, each of the driving devices 20, 30 and 40 may be integrated on the display panel 10 together with the plurality of signal lines S1 to Sn and D1 to Dm or the thin film transistors T1, T2 and T3, and the like.

Further, the driving devices 20, 30 and 40 may be integrated into a single chip. In this case, at least one of the driving devices 20, 30 and 40 or at least one circuit element constituting the driving devices 20, 30 and 40 may be positioned outside the single chip.

The light emitting device may include a switching thin film transistor connected to the scan lines S1 to Sn and the data lines D1 to Dm, a capacitor connected to the switching thin film transistor and the power supply line (not shown), and a driving thin film transistor connected to the capacitor and the power supply line. The capacitor may include a capacitor lower electrode and a capacitor upper electrode.

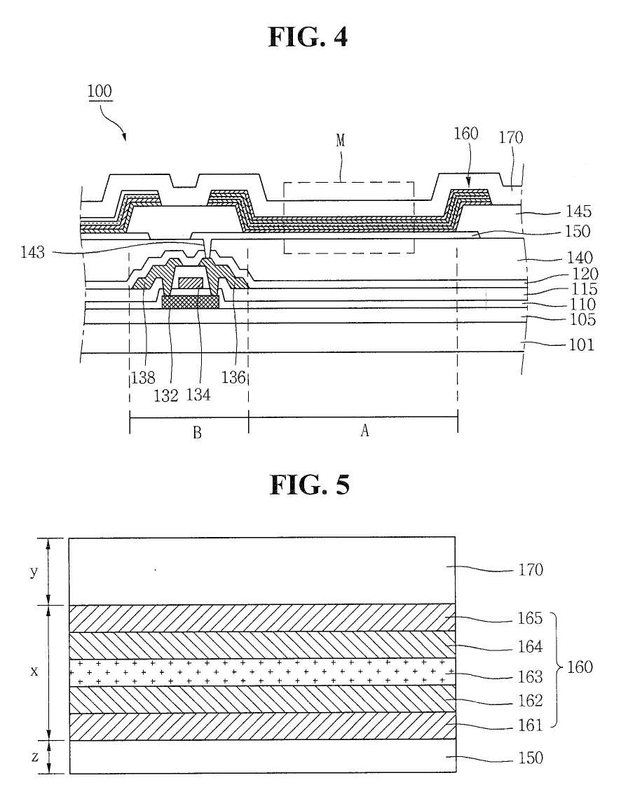

FIGS. 4 and 5 are cross-sectional views of the light emitting device.

As shown in FIG. 4, a light emitting device 100 may comprise a substrate 101, a buffer layer 105, a thin film transistor, first to fifth insulating films, a first electrode 150, a function layer 160, a second electrode 170, and so on.

The substrate 101 may be formed using a transparent glass or plastic material. The buffer layer 105 may be formed on the substrate 101. The buffer layer 105 can serve to prevent impurities, occurring from the substrate 101 in a manufacturing process of the light emitting device 100, from entering the device. The buffer layer 105 may be formed using a silicon nitride film (SiNx), a silicon oxide film (SiO₂) or a siliconoxynitride film (SiOxNx).

The thin film transistor may comprise a gate electrode 134, a source electrode 138, a drain electrode 136, and a semiconductor layer 132. The thin film transistor shown in this drawing has a coplanar structure. That is, the thin film transistor may have a top-gate structure in which the gate electrode 134 is disposed over the semiconductor layer 132.

In an embodiment of this document, the thin film transistor having the above structure will be described. However, this document can also be applied to a thin film transistor having a different structure.

The semiconductor layer 132 may be formed on the buffer layer 105. The semiconductor layer 132 may form a channel in the thin film transistor. The semiconductor layer 132 may be formed from a crystalline, poly-crystalline or amorphous material, representatively, silicon (Si), but not limited thereto.

A first insulating film 110, which may be referred to as a gate insulating film, is formed on the buffer layer 105 having the semiconductor layer 132 formed thereon. The first insulating film 110 may be formed from a material such as SiNx or SiO₂, but not limited thereto. The gate insulating film can insulate the gate electrode 134 from the source electrode 138 and the drain electrode 136, which will be described later.

The gate electrode 134 may be formed at a location corresponding to the semiconductor layer 132 on the first insulating film 110. The gate electrode 134 can turn on/off the thin film transistor in response to a data voltage supplied from a data line (not shown).

A second insulating film 115, which may be referred to as an interlayer insulating film, is formed on the first insulating film 110 having the gate electrode 134 formed thereon. The second insulating film 115 may be formed from a SiNx or SiO₂ material, but not limited thereto.

Contact holes may be formed in the first insulating film 110 and the second insulating film 115 in order to form the source electrode 138 and the drain electrode 136 connected to the semiconductor layer 132.

The source electrode 138 and the drain electrode 136 are connected to the semiconductor layer 132 through the contact holes, and may be projected upwardly from the second insulating film 115.

The gate electrode 134, the source electrode 138, and the drain electrode 136 may have a stack structure having at least one layer of chrome (Cr), aluminum (Al), molybdenum (Mo), silver (Ag), copper (Cu), titanium (Ti), tantalum (Ta) or an alloy thereof.

A third insulating film 120, which may be referred to as an inorganic passivation film, may be formed over the thin film transistor and the second insulating film 115. The inorganic passivation film is preferably formed to provide a passivation effect and an external light-shielding effect of the semiconductor layer 132.

A fourth insulating film 140, which may be referred to as a planarization film, may be formed over the substrate 101 over which the third insulating film 120 is formed. A via hole through which part of the thin film transistor is exposed may be formed in the fourth insulating film 140. In more detail, a via hole 143 through which part of the drain electrode 136 may be formed in the third insulating film 120 and the fourth insulating film 140. The fourth insulating film 140 may be formed using any one material selected from benzocyclobutene, polyimide, and acrylic resin, but not limited thereto.

The first electrode 150 may be formed on the fourth insulating film 140. The first electrode 150 may be electrically connected to the drain electrode 136 of the thin film transistor through the via hole 143 formed in the fourth insulating film 140 and the third insulating film 120.

The first electrode 150 may be an anode electrode. The first electrode 150 may be supplied with a voltage from the thin film transistor and may supply holes to the function layer 160.

A fifth insulating film 145, which is referred to as a pixel definition film, is formed over the fourth insulating film 140 and the first electrode 150. An aperture through which part of the first electrode 150 is exposed to define a light-emitting region A may be formed in the fifth insulating film 145. The fifth insulating film 145 may be formed from any one material selected from benzocyclobutene, polyimide, and acrylic resin, but not limited thereto.

The function layer 160 is formed on the first electrode 150. The function layer 160 may comprise a hole injection layer 161, a hole transport layer 162, a light-emitting layer 163, an electron transport layer 164, and an electron injection layer 165, which are sequentially formed over the first electrode 150. In the layers to constitute the function layer 160, the remaining constituent elements other than the light-emitting layer 163 are not indispensable. In other words, the remaining constituent elements may be included or excluded by taking the size of the light emitting device 100, efficiency of the light-emitting layer, the amount of electrons and holes, the transport ability, a material aspect, and so on in consideration synthetically. However, in this document, a description is given assuming that the hole injection layer 161, the hole transport layer 162, the light-emitting layer 163, the electron transport layer 164, and the electron injection layer 165 are all included.

The second electrode 170 may be opposite to the first electrode 150 with the function layer 160 intervened therebetween. The second electrode 170 may be a cathode electrode. The second electrode 170 may be formed using aluminum (Al), magnesium (Mg), silver (Ag), calcium (Ca) or an alloy thereof, but not limited thereto.

The function layer 160 is supplied with holes and electrons from the first electrode 150 and the second electrode 170 and generates exciton, so that light is emitted forwardly to display an image.

Hereinafter, the first electrode 150, the function layer 160, and the second electrode 170 of the light emitting device 100 having the above construction is described in detail.

FIG. 5 is an enlarged view of a portion “M” in FIG. 4.

As shown in FIG. 5, the light emitting device 100 according to this drawing has a bottom-emission structure.

In the light emitting device 100, the ratio in a thickness of each electrode and the function layer 160 has an close relationship in terms of emission efficiency, power consumption, and process efficiency of devices.

Accordingly, in the light emitting device 100 according to this document, the first electrode 150, the function layer 160, and the second electrode 170 are sequentially formed and have a predetermined thickness (width).

A thickness Z of the first electrode 150 may be substantially 0.29 to 0.35 times a thickness X of the function layer 160.

In the bottom-emission structure, when the thickness of the first electrode 150 is 0.29 times less than that of the function layer, electrical characteristics are degraded and power consumption increases. Further, the first electrode 150 is formed from a transparent material such as ITO or IZO. The above material has a rough surface, and is not uniformly deposited on the fourth insulating film 140 when being deposited thinly. Accordingly, only part of the first electrode 150 may be degraded and, therefore, dark spots may occur around the degraded portions. There may also be a problem in thickness control upon etching.

Meanwhile, when the thickness of the first electrode 150 is 0.35 times that of the function layer, transmittance of light decreases and a problem may arise in process, such as an increased etching time.

A thickness Y of the second electrode 170 may be substantially 0.29 to 0.69 times the thickness X of the function layer 160.

When the thickness of the second electrode 170 is 0.29 times less than that of the function layer, electrical characteristics may be degraded and power consumption may increase.

When the thickness of the second electrode is 0.69 times that of the function layer, the function layer may be damaged due to heat and stress, which occur in the process of depositing the second electrode on the function layer. Further, if the thickness of the second electrode 170 is thick, the ratio of holes supplied from the first electrode 150 does not coincide with the ratio of electrons supplied from the second electrode 170. It may break the balance of charges and make the formation of exciton irregular.

Accordingly, the light emitting device according to this document may have good emission efficiency and uniformity of light, which is output from sub pixels, when the first electrode 150, the function layer 160, and the second electrode 170 have the above numerical values. The light emitting device may also have lower power consumption by contrast with emission efficiency, and is efficient in terms of a process such as etching.

The structure of the function layer 160 is described below. At least one of the hole injection layer 161 and the hole transport layer 162 may be sequentially formed over the first electrode 150 between the first electrode 150 and the light-emitting layer 163 and, therefore, can make smooth the transport of holes from the first electrode 150 to the light-emitting layer 163.

At least one of the electron transport layer 164 and the electron injection layer 165 may be sequentially formed over the light-emitting layer 163 between the light-emitting layer 163 and the second electrode 170 and, therefore, can make smooth the transport of electrons from the second electrode 170 to the light-emitting layer 163.

At least one of the light-emitting layer 163, the hole injection layer 161, the hole transport layer 162, the electron transport layer 164, and the electron injection layer 165 may comprise an organic material or an inorganic material.

The electron injection layer 165 formed below the second electrode 170 may be lithium fluoride (LiF) to form a strong dipole. The dipole may be formed by a polarization phenomenon in which a nucleus and an electron inside an atom each have an opposite polarity.

Lithium fluoride (LiF) has a strong ionic bond characteristic. In general, bonds between chemical elements can be largely classified into covalent bonds and ionic bonds. They can be classified according to the absolute value of a difference in the electronegativity of respective chemical elements. In general, when the absolute value of a difference in the electronegativity of respective chemical element is 1.67 or higher, it can be said that bonds between the chemical elements are ionic bonds.

In lithium fluoride (LiF), the electronegativity of lithium is 3.98 and the electronegativity of fluorine is 0.98. Thus, the absolute value of a difference in the electronegativity of lithium and fluorine becomes 3. The result shows that lithium fluoride (LiF) has very strong ionic bonds. Strong bonds of ionic bonds form a dipole within the bonds. In other words, lithium fluoride (LiF) is a material having strong ionic bonds to form a dipole, and a distance between the atoms of the two chemical elements is very close.

Lithium fluoride (LiF) forms a strong dipole and, therefore, increases the injection of electrons into the light-emitting layer 160. Accordingly, emission efficiency can be improved and a driving voltage can be lowered.

Furthermore, a lithium complex (Liq) has polarizability weaker than that of lithium fluoride (LiF). However, because the lithium complex (Liq) is used as a material of the electron injection layer, it can increase electron injection and improve emission efficiency.

The hole injection layer 161 or the electron injection layer 168, which is formed from the organic material, may further comprise an inorganic material. Further, the inorganic material may become a metal compound. The metal compound may comprise alkali metal or alkali earth metal. The metal compound comprising the alkali metal or the alkali earth metal may be any one selected from a group comprising LiF, NaF, KF, RbF, CsF, FrF, BeF₂, MgF₂, CaF₂, SrF₂, BaF₂, and RaF₂.

In the light emitting device 100, the hole mobility is generally 10 times faster than the electron mobility. Thus, the amount of holes injected into the light-emitting layer 163 differs from the amount of electrons injected into the light-emitting layer 163. Accordingly, emission efficiency of the light emitting device 100 may be degraded.

In this case, the inorganic material may function to lower a highest level of a valence band of the hole injection layer 161 formed from the organic material and a lowest level of a conduction band of the electron injection layer 165 formed from the organic material.

Therefore, the inorganic material within the hole injection layer 161 or the electron injection layer 165 may function to lower the mobility of holes injected from the first electrode to the light-emitting layer 163 or increase the mobility of electrons injected from the second electrode to the light-emitting layer 163. Accordingly, as the balance of the holes and the electrons is maintained, emission efficiency can be improved.

Furthermore, in the light emitting device in accordance with an embodiment of this document, a fluorescent material or a phosphorescent material may be used as the material of the light-emitting layer.

In recent years, as the internal quantum efficiency of the phosphorescent material increases, the phosphorescent material will be mainly described as an example.

A red light-emitting layer comprises a host material comprising CBP (carbazole biphenyl) or mCP (1,3-bis(carbazol-9-yl)), and may be formed using a phosphorescent material comprising a dopant comprised of one or more selected from a group comprising PIQIr(acac)(bis(1-phenylisoquinoline)acetylacetonate iridium), PQIr(acac)(bis(1-phenylquinoline)acetylacetonate iridium), PQIr(tris (1-phenylquinoline)iridium), and PtOEP(octaethylporphyrin platinum). Further, there are an iridium-based transfer metal compound, such as iridium(III)(2-(3-methylphenyl)-6-methylquinolinato-N,C2′)(2,4-pentanedionate-O,O), platinum porphyrin and so on. Alternatively, the red light-emitting layer may be comprised of a fluorescent material comprising PBD:Eu(DBM)3(Phen) or perylene.

A blue light-emitting layer comprises a host material comprising CBP or mCP, and may be formed using a phosphorescent material comprising a dopant material comprising (4,6-F2ppy)2Irpic. There are also iridium-based transfer metal compounds such as (3,4-CN)3Ir, (3,4-CN)2Ir (picolinic acid), (3,4-CN)2Ir(N3), (3,4-CN)2Ir(N4), and (2,4-CN)3Ir. Alternatively, the blue light-emitting layer may be formed from a fluorescent material comprising any one selected from a group comprising spiro-DPVBi, spiro-6P, distylbenzene (DSB), distrylarylene (DSA), and PFO-based polymers, and PPV-based polymer.

A green light-emitting layer comprises a host material comprising CBP or mCP, and may be formed from a phosphorescent material comprising a dopant material comprising Ir(ppy)3(fac tris(2-phenylpyridine)iridium). There may also be tris(2-:pyridine)Ir(III) and so on. Alternatively, the green light-emitting layer may also be formed using a fluorescent material comprising Alq3(tris(8-hydroxyquinolino)aluminum).

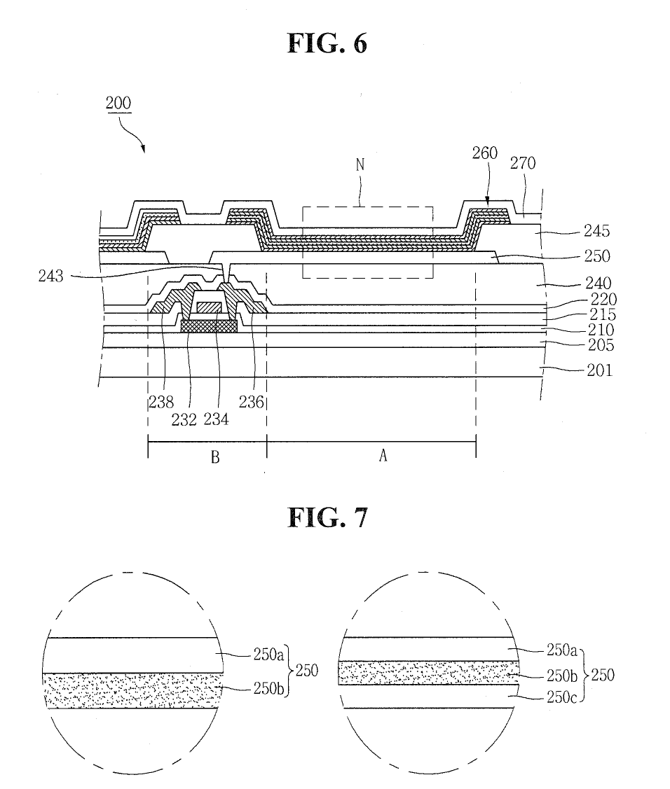

FIGS. 6 to 8 are cross-sectional views of another structure of the light emitting device.

Referring to FIGS. 6 and 7, FIG. 6 has the same structure as that of the light emitting device 100 described with reference to FIG. 4. However, the light emitting device 200 according to the exemplary embodiment has a top-emission structure and, therefore, differs from the light emitting device 100 in the stack structure of a first electrode 250 and the ratio of a thickness of each electrode and a function layer 260.

Hereinafter, in describing FIGS. 6 and 7, the same parts as those of FIG. 4 will not be described, and characteristics in accordance with another embodiment of this document will be mainly described.

FIG. 7 is an enlarged view of the first electrode 250 of FIG. 6.

The first electrode 250 is formed on a fourth insulating film 240 and may have a double layer structure comprising a reflection electrode 250b connected to a thin film transistor through a via hole 243, and a first transparent electrode 250a formed on the reflection electrode 250b. The reflection electrode 250b may be electrically connected to a drain electrode 236 of the thin film transistor, and the first transparent electrode 250a may be electrically connected to the reflection electrode 250b.

In a top-emission structure, the reflection electrode 250b may be disposed on the lower side of the first electrode 250, and may function to return light, generated from the function layer 260, to the second electrode 270 when the light generated from the function layer 260 is not output upwardly from the second electrode 270, but output upwardly from the first electrode 250. The reflection electrode 250b may be formed from any one of silver (Ag), aluminum (Al), and nickel (Ni), which have a good reflectance, but not limited thereto.

Alternatively, the first electrode 250 is formed on the fourth insulating film 240 and may have a triple layer structure comprising a second transparent electrode 250c connected to the drain electrode 236 of the thin film transistor through the via hole 243, and a reflection electrode 250b and a first transparent electrode 250a formed over the second transparent electrode 250c.

If the first electrode 250 further comprises the second transparent electrode 250c below the reflection electrode 250b compared with the case where it comprises only the reflection electrode 250b and the first transparent electrode 250a, the contact ability when being connected to the thin film transistor can be improved. The first transparent electrode 250a and the second transparent electrode 250c may be formed from either ITO or IZO, but not limited thereto.

FIG. 8 is an enlarged view of a portion “N” in FIG. 6.

In the light emitting device 200, the ratio in a thickness of each electrode and the function layer 260 has an organic relationship in terms of emission efficiency, power consumption, and process efficiency of the device.

Referring to FIG. 8, in the light emitting device 200 in accordance with this document, the first electrode 250, the function layer 260, and the second electrode 270 are sequentially formed and have a predetermined thickness (width).

A thickness Y of the second electrode 270 may be substantially 0.03 to 0.035 times a thickness X of the function layer 260.

The top-emission structure may have characteristics opposite to those of the bottom-emission structure. When the thickness of the second electrode 270 is 0.03 times less than that of the function layer, the electrical conductivity may be lowered and, therefore, power consumption may increase or the leakage current may occur. It may also be difficult to control thickness upon etching.

When the thickness of the second electrode 270 is 0.035 times that of the function layer, transmittance may decrease and transmittance of light may be difficult. In addition, stress due to heat is great, and a phenomenon in which the second electrode is bent one-sidely due to stress when it is thickly deposited on an opposite side of the substrate may occur.

A thickness Z of the first electrode 250 may be substantially 0.6 to 0.79 times the thickness X of the function layer 260.

When the thickness of the first electrode 250 is 0.6 times less than that of the function layer, electrical characteristics may be degraded, resulting in increased power consumption. When the thickness of the first electrode 250 is 0.79 times that of the function layer, the ratio of electrons supplied from the second electrode 270 does not coincide with the ratio of holes supplied from the first electrode 250. Thus, the balance of charges may not be maintained, thereby making the formation of exciton irregular.

Accordingly, the light emitting device according to this document may have good emission efficiency and uniformity of light, which is output from sub pixels, when the first electrode 250, the function layer 260, and the second electrode 270 have the above numerical values. The light emitting device may also have lower power consumption by contrast with emission efficiency, and is efficient in terms of a process such as etching.

The structure of the function layer is described below. At least one of a hole injection layer 261 and a hole transport layer 262 may be sequentially formed over the first electrode 250 between the first electrode 250 and a light-emitting layer 263 and, therefore, can make smooth the transport of holes from the first electrode 250 to the light-emitting layer 263.

Further, at least one of an electron transport layer 264 and an electron injection layer 265 may be sequentially formed over the light-emitting layer 263 between the light-emitting layer 263 and the second electrode 270 and, therefore, can make smooth the transport of electrons from the second electrode 270 to the light-emitting layer 263.

At least one of the light-emitting layer 263, the hole injection layer 261, the hole transport layer 262, the electron transport layer 264, and the electron injection layer 265 may be formed from an organic material or an inorganic material.

The electron injection layer 265 formed below the second electrode 270 may be lithium fluoride (LiF) to form a strong dipole. Lithium fluoride (LiF) forms a strong dipole and thus increases the injection of electrons into the light-emitting layer 263. Accordingly, emission efficiency can be improved and a driving voltage can be lowered.

The hole injection layer 261 or the electron injection layer 265, which is formed from the organic material, may further comprise an inorganic material. The inorganic material may further comprise a metal compound. The metal compound may comprise alkali metal or alkali earth metal. The metal compound comprising the alkali metal or the alkali earth metal may be any one selected from a group comprising LiF, NaF, KF, RbF, CsF, FrF, BeF₂, MgF₂, CaF₂, SrF₂, BaF₂, and RaF₂.

In the light emitting device 200, the hole mobility is generally 10 times or more faster than the electron mobility. Thus, the amount of holes injected into the light-emitting layer 263 differs from the amount of electrons injected into the light-emitting layer 263. Accordingly, emission efficiency of the light emitting device 200 may be degraded.

In this case, the inorganic material may function to lower a highest level of a valence band of the hole injection layer 261 formed from the organic material and a lowest level of a conduction band of the electron injection layer 265 formed from the organic material.

Therefore, the inorganic material within the hole injection layer 261 or the electron injection layer 265 may function to lower the mobility of holes injected from the first electrode to the light-emitting layer 263 or increase the mobility of electrons injected from the second electrode to the light-emitting layer 263. Accordingly, as the balance of the holes and the electrons is maintained, emission efficiency can be improved.

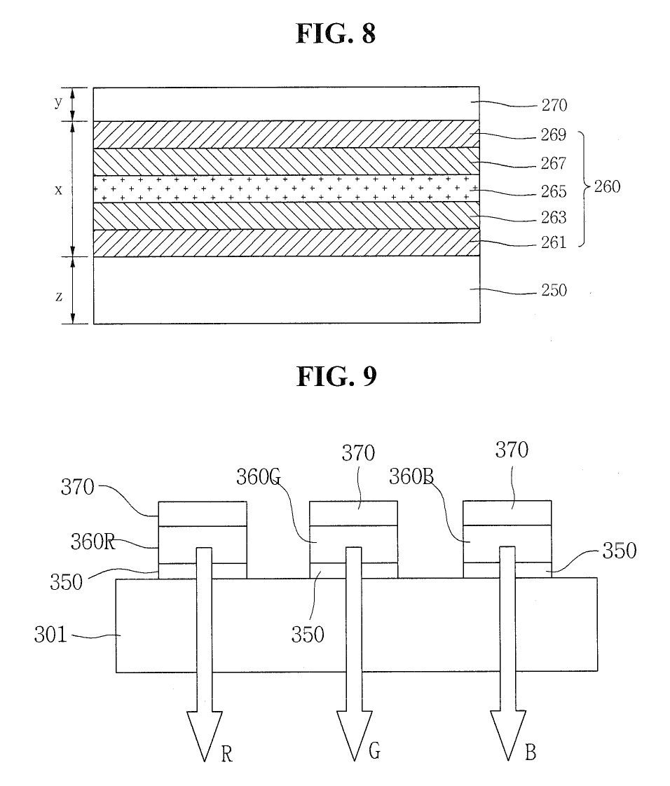

FIGS. 9 to 11 illustrate various implementations of a color image display method in the light emitting device.

In FIGS. 9 to 11, a reference numeral 301 indicates a substrate, 350 a first electrode, and 370 a second electrode.

FIG. 9 illustrates a color image display method in a light emitting device separately including a red emitting layer 360R, a green emitting layer 360G and a blue emitting layer 360B which emit red, green and blue light, respectively.

The red, green and blue light produced by the red, green and blue emitting layers 360R, 360G and 360B is mixed to display a color image.

It may be understood in FIG. 9 that the red, green and blue emitting layers 360R, 360G and 360B each include an electron transport layer, a hole transport layer, and the like, on upper and lower portions thereof. It is possible to variously change the arrangement and the structure between the additional layers such as the electron transport layer and the hole transport layer and each of the red, green and blue emitting layers 360R, 360G and 360B.

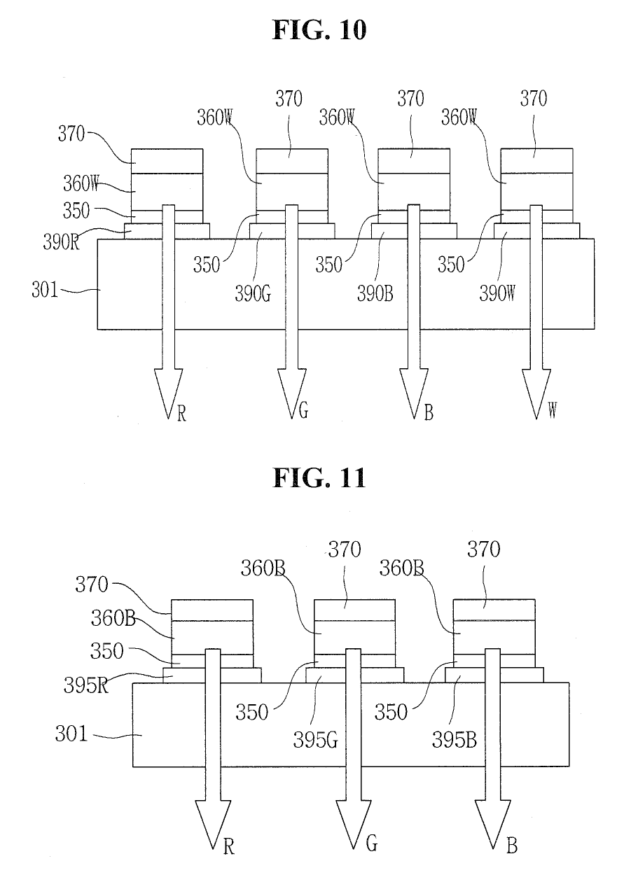

FIG. 10 illustrates a color image display method in a light emitting device including a white emitting layer 360W, a red color filter 390R, a green color filter 390G, a blue color filter 390B, and a white color filter 390W.

As shown in FIG. 10, the red color filter 390R, the green color filter 390G, the blue color filter 390B, and the white color filter 390W each transmit white light produced by the white emitting layer 360W to produce red light, green light, blue light, and white light. The red, green, blue, and white light is mixed to display a color image. The white color filter 390W may be removed depending on color sensitivity of the white light produced by the white emitting layer 360W and combination of the white light and the red, green and blue light.

While FIG. 10 has illustrated the color display method of four subpixels using combination of the red, green, blue, and white light, a color display method of three subpixels using combination of the red, green, and blue light may be used.

It may be understood in FIG. 10 that the white emitting layer 360W includes an electron transport layer, a hole transport layer, and the like, on upper and lower portions thereof. It is possible to variously change the arrangement and the structure between the additional layers such as the electron transport layer and the hole transport layer and the white emitting layer 360W.

FIG. 11 illustrates a color image display method in a light emitting device including a blue emitting layer 360B, a red color change medium 395R, a green color change medium 395G, a blue color change medium 395B.

As shown in FIG. 11, the red color change medium 395R, the green color change medium 395G, and the blue color change medium 395B each transmit blue light produced by the blue emitting layer 360B to produce red light, green light and blue light. The red, green and blue light is mixed to display a color image.

The blue color change medium 395B may be removed depending on color sensitivity of the blue light produced by the blue emitting layer 360B and combination of the blue light and the red and green light.

It may be understood in FIG. 11 that the blue emitting layer 360B includes an electron transport layer, a hole transport layer, and the like, on upper and lower portions thereof. It is possible to variously change the arrangement and the structure between the additional layers such as the electron transport layer and the hole transport layer and the blue emitting layer 360B.

While FIGS. 9 and 11 have illustrated and described the light emitting device having a bottom emission structure, the exemplary embodiment is not limited thereto. The light emitting device according to the exemplary embodiment may have a top emission structure, and thus the structure of the light emitting device according to the exemplary embodiment may be changed depending on the top emission structure.

While FIGS. 9 to 11 have illustrated and described three kinds of color image display method, the exemplary embodiment is not limited thereto. The exemplary embodiment may use various kinds of color image display method whenever necessary.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art.

1-8. (canceled)

9. A light emitting device comprising:
a substrate including a thin film transistor;
an insulating film disposed over the thin film transistor;
a first electrode disposed over the thin film transistor and connected to the thin film transistor;
a function layer including at least one of a hole injection layer, a hole transport layer, a light-emitting layer, an electron transport layer, and an electron injection layer, which are sequentially disposed over the first electrode; and
a second electrode disposed on the function layer,
wherein a thickness of the first electrode is substantially 0.6 to 0.79 times a thickness of the function layer, and
a thickness of the second electrode is substantially 0.03 to 0.035 times the thickness of the function layer.

10. The light emitting device of claim 9, wherein the first electrode comprises any one of a double layer structure having a reflection electrode/a first transparent electrode and a triple layer structure having a second transparent electrode/a reflection electrode/a first transparent electrode.

11. The light emitting device of claim 9, wherein the first electrode comprises an anode electrode, and the second electrode comprises a cathode electrode.

12. The light emitting device of claim 10, wherein the reflection electrode comprises any one of silver (Ag), aluminum (Al), and nickel (Ni).

13. The light emitting device of claim 9, wherein at least one of the light-emitting layer, the hole injection layer, the hole transport layer, the electron transport layer, and the electron injection layer comprise an organic material or an inorganic material.

14. The light emitting device of claim 13, wherein the hole injection layer comprising the organic material or the electron transport layer comprising the organic material further comprises an inorganic material.

15. The light emitting device of claim 14, wherein a highest level of a valence band of the hole injection layer further comprising the inorganic material is lower than a highest level of a valence band of the hole injection layer comprising only the organic material.

16. The light emitting device of claim 14, wherein a lowest level of a conduction band of the electron injection layer further comprising the inorganic material is lower than a lowest level of a conduction band of the electron injection layer comprising only the organic material.

17. The light emitting device of claim 9, wherein the light-emitting layer comprises either a fluorescent material or a phosphorescent material.

18. The light emitting device of claim 9, wherein the electron injection layer comprises either lithium fluoride (LiF) or a lithium complex (Liq).

19. (canceled)

20. A light emitting device comprising:
a substrate including a thin film transistor;
an insulating film disposed over the thin film transistor;
a first electrode disposed over the thin film transistor and connected to the thin film transistor;
a function layer including at least one of a hole injection layer, a hole transport layer, a light-emitting layer, an electron transport layer, and an electron injection layer, which are sequentially disposed over the first electrode; and
a second electrode disposed on the function layer,
wherein a thickness of the first electrode is substantially 0.6 to 0.79 times a thickness of the function layer, and a thickness of the second electrode is substantially 0.03 to 0.035 times the thickness of the function layer,
wherein a highest level of a valence band of a hole injection layer including an inorganic material layer is lower than a highest level of a valence band of the hole injection layer including a organic material without the inorganic material, and
wherein a lowest level of a conduction band of a electron injection layer including an inorganic material is lower than a lowest level of a conduction band of the electron injection layer including an organic material without the inorganic material.

21. (canceled)
